(19) United States
(12) Patent Application Publication
(10) Pub. No.: US 2021/0336420 A1
(43) Pub. Date: Oct. 28, 2021

(54) VCSEL WITH INTRA-CAVITY OXIDE CONFINEMENT STRUCTURE

(71) Applicant: II-VI Delaware, Inc., Wilmington, DE (US)

(72) Inventor: Giuseppe Tandoi, Zurich (CH)

(73) Assignee: II-VI Delaware, Inc., Wilmington, DE (US)

(21) Appl. No.: 16/858,909

(22) Filed: Apr. 27, 2020

(51) Int. Cl. H01S 5/183

(52) U.S. Cl. CPC H01S 5/18327

(57) ABSTRACT

A vertical cavity surface emitting laser (VCSEL) device includes an oxide aperture layer positioned in close proximity to the active region of the device, typically within the cavity itself, as opposed to being positioned in the top DBR of the VCSEL. Reducing the spacing between the active region and the oxide aperture layer has been found to reduce the spread of current across the surface of the active region, allowing for a lower threshold current to be achieved. The closer positioning of the oxide aperture layer also reduced optical absorption and series resistance. The oxide aperture layer may be located at the first null in the standing wave pattern between the active region and the top DBR to minimize divergence of the beam and control the optical mode.

### TECHNICAL FIELD

The present invention relates to a vertical cavity surface emitting laser (VCSEL) device and, more particularly, to a VCSEL having an oxide aperture layer positioned in close proximity to the active region to optimize parameters such as threshold current and optical mode confinement.

### BACKGROUND OF THE INVENTION

A VCSEL has a laser cavity that is sandwiched between and defined by two mirror stacks. A VCSEL is typically fabricated on a semiconductor substrate (in many cases a GaAs or InP substrate), with a “bottom” mirror stack formed on the top surface of the substrate, and then covered by the laser cavity and “top” mirror stack. Each mirror stack includes a number of epitaxial layers of alternating refractive index values (i.e., alternating between “high” and “low” refractive index values. The cavity region itself includes one or more quantum well structures. As light passes from a layer of one index of refraction to another, a portion of the light is reflected, creating a diffractive Bragg reflector (DBR) structure. By using a sufficient number of alternating layers, a high percentage of light is reflected and creates a standing wave pattern across the cavity.

At a sufficiently high bias current (referred to as the threshold current), the injected minority carriers form a population inversion in the quantum wells, producing gain. When the optical gain exceeds the total loss in the two mirrors, laser emission occurs through an outer surface of one of mirror stacks. When compared to conventional edge-emitting laser diodes, a VCSEL offers lower threshold currents, low-divergence circular output beams, and longitudinal single mode emission (as well as other benefits in particular applications).

In some configurations, an additional layer is included within the top DBR and is typically positioned in the lower layers closer to the active region. Referred to as an oxide aperture layer, this layer typical is one of the original DBR layers that is modified to include a higher concentration of aluminum. A set of process steps is used to oxidize the majority of this layer, leaving a central portion in its original composition to form an “aperture” for confining the beam emitted from the active region.

### SUMMARY OF THE INVENTION

The present invention relates to a vertical cavity surface emitting laser (VCSEL) device and, more particularly, to a VCSEL having an oxide aperture layer formed in close proximity to the active region of the VCSEL, typically within the cavity itself, to optimize parameters such as threshold current and optical mode confinement.

In accordance with an exemplary embodiment of the present invention, an oxide aperture layer is located within the laser cavity, between the active region's multiple quantum well (MQW) structure and the cavity boundary with the top DBR. In selected embodiments, the oxide aperture layer may be located at the first null in the standing wave pattern adjacent to the active region. In this case, the oxide aperture layer is immediately adjacent to where emission occurs and thus minimizes the current spread in the active region and controls the optical mode. Since the oxide aperture layer is placed adjacent to the quantum well structure, the shorter distance between the QWs and the oxide aperture layer allows for the threshold current and vertical resistance to be reduced.

One exemplary embodiment of the present invention may take the form of a VCSEL comprising a first distributed Bragg reflector (DBR) formed on a substrate and a second DBR positioned over the first DBR (where each DBR comprises a stack of layers of alternating refractive index value), the combination of the first DBR and second DBR forming a resonant structure supporting a standing wave of lasing field intensity. The VCSEL also includes an active region comprising a MQW structure formed between the first DBR and the second DBR, with a laser cavity defined as spanning between a first standing wave intensity peak and a second standing wave intensity peak closest to either side of the active region and an oxide aperture layer located within the laser cavity between the active region and the second DBR.

Other and further embodiments and features of the present invention will become apparent during the course of the following discussion and by reference to the accompanying drawings.

### BRIEF DESCRIPTION OF THE DRAWINGS

Referring now to the drawings, where like numerals represent like parts in several views:

FIG. 1 illustrates a prior art VCSEL, showing a typical placement of an oxide aperture within a p-type distributed Bragg reflector (DBR) used to form the top mirror of the VCSEL;

FIG. 2 contains a plot depicting the aluminum content within the structure of FIG. 1, as well a plot of the standing wave pattern of the field intensity formed within the structure;

FIG. 3 shows a portion of an exemplary VCSEL structure formed in accordance with the present invention to utilize an oxide aperture layer that is positioned in the laser cavity in close proximity to the active region;

FIG. 4 contains plots of aluminum content and field intensity standing wave for the inventive structure of FIG. 3;

FIG. 5 contains a plot of current spread (as defined by the FWHM of the current profile) as a function of the separation between the oxide aperture layer and the active region;

FIG. 6 contains plots associated with an alternative embodiment of the present invention including an oxide aperture layer positioned in the laser cavity similar to that of FIG. 3, in this case comprising a structure where the bottom DBR is positioned adjacent to the active region, creating a laser cavity of length λ/2;

FIG. 7 contains plots of a modification of the structure associated with FIG. 6, in this case retaining the shorter cavity length of λ/2, but positioning the oxide aperture layer beyond the cavity boundary (still in relatively close proximity to the active region by virtue of the reduction in cavity length);

FIG. 8 contains plots associated with another prior art VCSEL structure, referred to as an “inverted cavity” structure and defined by DBR layers of high aluminum concentration located near the active region; and

FIG. 9 contains plots of another embodiment of the present invention, based upon a combination of the inverted cavity structure associated with FIG. 8, and the intra-cavity positioning of the oxide aperture layer as shown in FIGS. 3 and 4.

### DETAILED DESCRIPTION

Prior to describing the details of the inventive concepts and features related to modifying the positioning of an oxide aperture layer with respect to a VCSEL active region, the basic structure of a prior art VCSEL including an oxide aperture layer will be briefly reviewed.

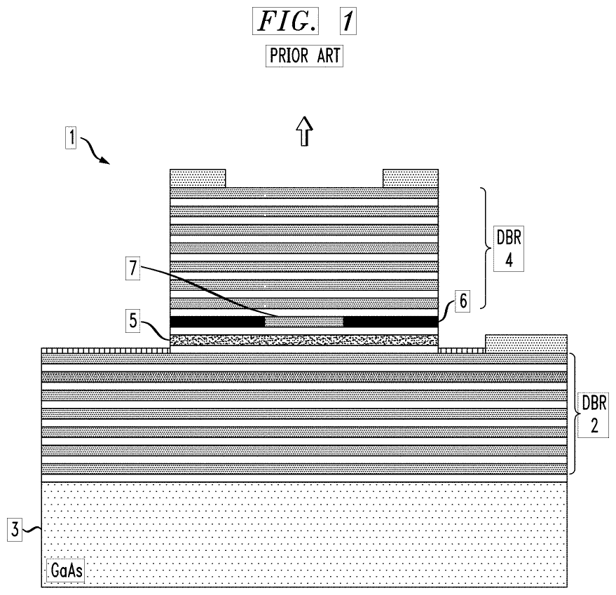

FIG. 1 is a simplified cut-away view of a conventional prior art VCSEL 1, which as mentioned above in general takes the form of an active region (including an MQW structure) positioned between a pair of top and bottom “mirrors” that define the boundaries of the laser cavity. Here, a first mirror is created by a first DBR 2 that is formed on a substrate 3. A second mirror is defined by a second (opposing) DBR 4. In a GaAs-based VCSEL device structure, the DBRs are formed of alternating layers of GaAs and AlGaAs, with first DBR 2 typically being formed of n-type layers of GaAs and AlGaAs, and second DBR 4 formed of p-type layers of these same materials. The laser's cavity is defined by the region between first DBR 2 and second DBR 4, and includes an active region 5, formed as a MQW structure. The prior art VCSEL structure 1 of FIG. 1 also includes an oxide aperture layer 6, which is located within second DBR 4, as shown.

Free carriers in the form of holes and electrons are injected into the quantum wells of active region 5 when the PN junction is forward biased by an applied electrical current. At a sufficiently high bias current (defined hereinafter as the “threshold current”) the injected carriers form a population inversion in the quantum wells that produces optical gain.

Oxide aperture layer 6 is typically formed by oxidizing a layer of AlGaAs within the stack of second DBR 4 that has been intentionally formed to exhibit a high concentration of aluminum with respect to the remaining AlGaAs layers within the structure of second DBR 4. The oxidation process is time-limited such that a central region the layer's aluminum content is not affected, thus defining an “aperture” 7 in layer 6. VCSELs formed to include this oxide aperture layer exhibit improved performance over those having no similar structure, since the presence of the oxide functions to confine the beam waist of the laser output. In particular, the inclusion of an oxide material within the structure laterally defines the current injection area into active region 5.

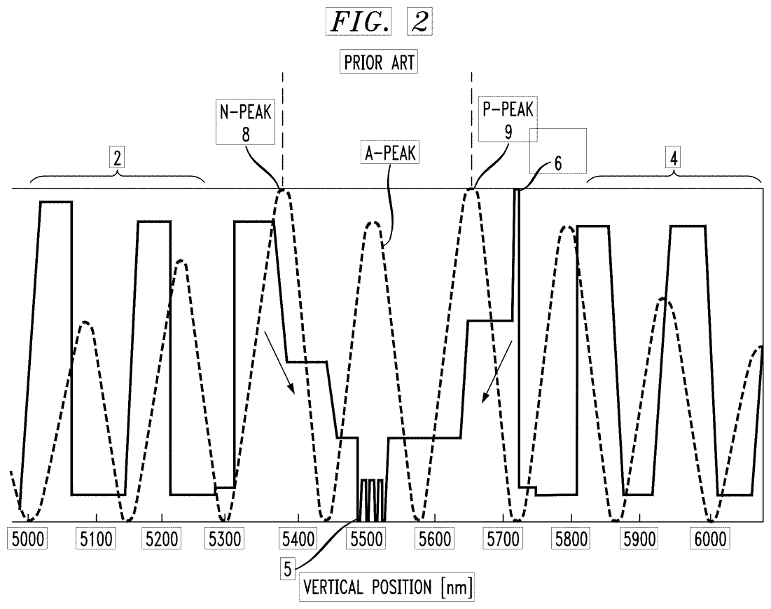

FIG. 2 is a plot depicting the aluminum content within the AlGaAs layers within first (bottom) DBR 2 (in the left-hand portion of the plot) and second (top) DBR 4 (in the right-hand portion of the plot), with active region 5 shown by the MQW structure in the central area between the two DBRs. Overlaid on this plot is the field intensity created by injecting current into the structure, which takes the form of a standing wave pattern, forming a resonant structure between the mirrors created by bottom DBR 2 and top DBR 4. The cavity 7 of the structure is defined as region spanning between a first intensity peak below active region 5 (denoted as N-peak 8 in FIG. 2) and a first intensity peak above active region 5 (denoted as P-peak 9 in FIG. 2). Oxide aperture layer 6 is shown as the relatively high aluminum content layer within top DBR 4 and is shaded for identification purposes. In this typical prior art arrangement, it is clear that oxide aperture layer 6 is positioned beyond the boundaries of the laser cavity.

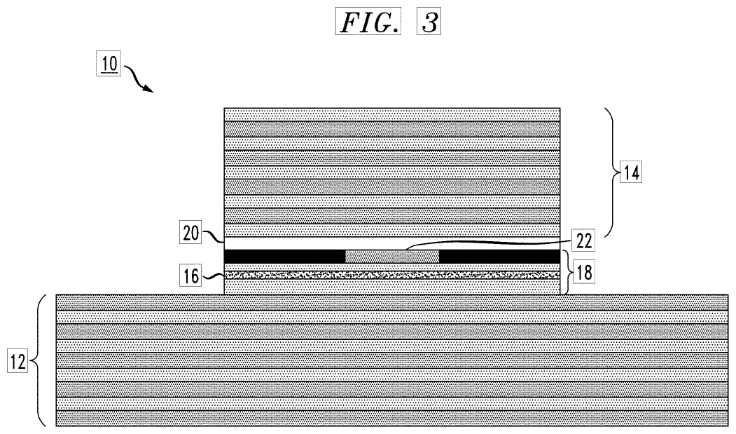

FIG. 3 illustrates a portion of a VCSEL structure 10 formed in accordance with the principles of the present invention to intentionally position an oxide aperture layer in close proximity to the active region of the device (in most cases, within the laser cavity itself). As discussed in detail below, the relatively close spacing between the active region and the oxide aperture layer has been found to allow for a significant reduction in the threshold current required to energize the device, as well as provide additional mode confinement of the optical output beam. For the sake of clarity, only the DBR mirror structures and laser cavity of this VCSEL are shown, since the subject matter of the present invention is particularly directed to the interaction between the oxide aperture layer and the laser cavity.

Referring to FIG. 3, VCSEL 10 is shown as comprising a first (bottom) DBR 12 and a second (top) DBR 14, with an active region 16 located within a cavity 18 formed between the two DBRs. The arrangement of the DBRs and active region is essentially the same as in conventional VCSEL structures, such as prior art VCSEL 1 discussed above.

In contrast to the arrangement of prior art VCSEL 1, VCSEL 10 of the present invention is shown as including an oxide aperture layer 20 that is positioned within laser cavity 18, in relatively close proximity to active region 16. It is to be recalled that “oxide aperture layer 20” in fact comprises a central region that is not oxidized and defines an aperture 22 through which the lasing output from active region 16 is confined as it propagates upward (in this depiction) to exit through second DBR 14.

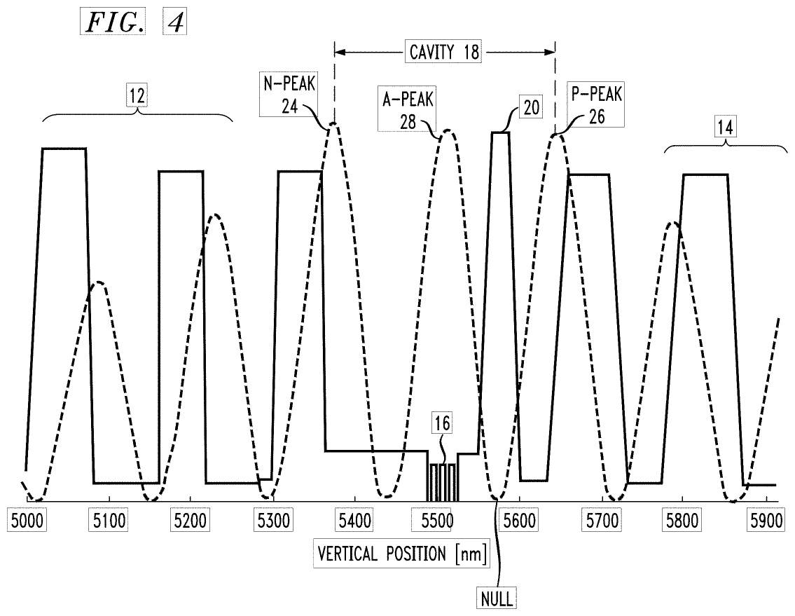

FIG. 4 contains a plot, similar to that of FIG. 2, depicting the aluminum content within the AlGaAs layers forming first DBR 12 (in the left-hand portion of the plot) and second DBR 14 (in the right-hand portion of the plot), with active region 16 shown by the MQW structure in the central area between the two DBRs. Overlaid on this plot is the field intensity created by injecting current into the structure, which takes the form of a standing wave pattern, providing a resonant structure. Laser cavity 18 of the structure is defined as the region spanning between a first intensity peak below active region 16 (denoted as N-peak 24 in FIG. 4) and a first intensity peak above active region 16 (denoted as P-peak 26 in FIG. 4).

In accordance with the principles of the present invention, oxide aperture layer 20, indicated here as a relatively thin layer with a high aluminum content (and again shaded to assist in its identification), is positioned located within laser cavity 18, as evidenced by its position with respect to active region 16 and P-peak 26. By positioning oxide aperture layer 20 within close proximity to active region 16, there is a reduced opportunity for the applied current to spread laterally away from the central area of active region 16. This ability to confine the current allows for the required threshold current to be significantly reduced when compared to the conventional prior art VCSELs.

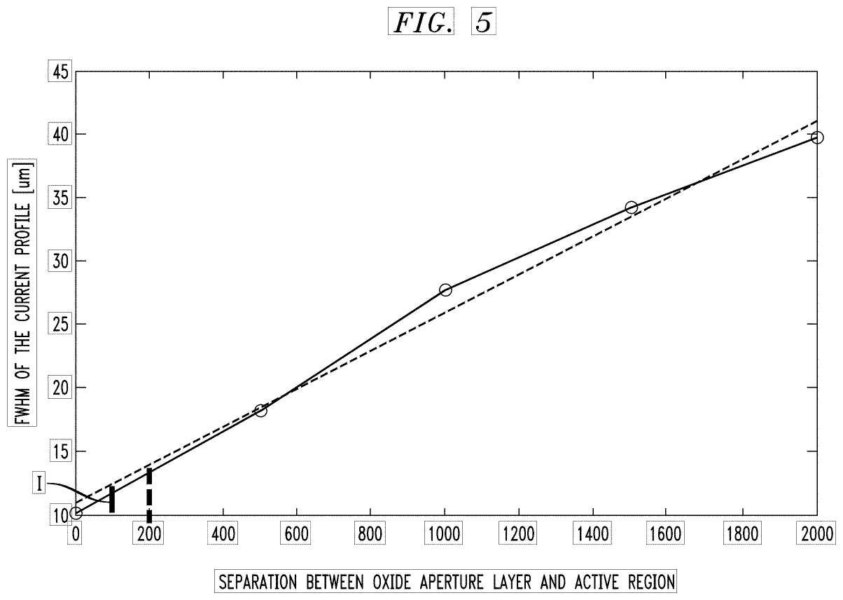

FIG. 5 illustrates the relationship between current confinement and spacing between the active region and oxide aperture layer. In particular, FIG. 5 plots the FWHM of the current profile as a function of the spacing between oxide aperture layer 20 and active region 16. The FWHM plot clearly demonstrates a linear increase in current spread as the separation increases. In typical prior art configurations, such as that discussed above in association with FIGS. 1 and 2, the spacing is on the order of about 200 nm and thus the current profile exhibits a related FWHM as shown. In accordance with the principles of the present invention, reducing the spacing between oxide aperture layer 20 and active region 16 to a value below the prior art gap spacing will result in decreasing the FWHM of its current profile, shown by indicator I in FIG. 5.

The relationship between controlling the separation between active region 16 and oxide aperture layer 20 in order to achieve an acceptable amount of current spread is clear. Moreover, by reducing the spread of current across this region, the threshold current required to provide lasing may be reduced as well, a significant improvement over the prior art. The reduction of spacing by this amount also results, as discussed above, in placing oxide aperture layer 20 within laser cavity 18.

Returning to the discussion of FIG. 4, this positioning of oxide aperture layer 20 within cavity 18 results in making the cavity even more asymmetric than in conventional VCSELs. This is indicated by the increase in intensity of the field peak that overlaps active region 16 when compared to the prior art values shown in FIG. 2 (compare A-peak of FIG. 2 to A-peak of FIG. 4). Indeed, in the conventional prior art structure, the intensity of the peak associated with the active region is less than that of the boundary peaks on either side. In contrast, the structure of the inventive VCSEL results in the A-peak being in excess of both the N-peak and P-peak. The presence of a strong intensity peak in active region 16 also functions to reduce the level of threshold current required to activate the device. Moreover, reducing the magnitudes of the N-peak and P-peak intensities also reduces optical absorption within the device, therefore resulting in further reduction in threshold current and a corresponding increase in slope efficiency.

While oxide aperture layer 20 may be located at a various positions between active region 16 and P-peak 26, the specific configuration associated with FIG. 4 intentionally locates oxide aperture layer 20 at a “null” in the standing wave pattern of the field. This null position therefore minimizes the optical interaction of oxide aperture layer 20 with the optical beam emitted from active region 16, providing the additional advantage of reducing the numerical aperture of the emitted beam. This position is also associated with a substantially reduced current spread, as evidenced by the plot in FIG. 5, which as mentioned above lowers the threshold current and reduces the generated beam waist.

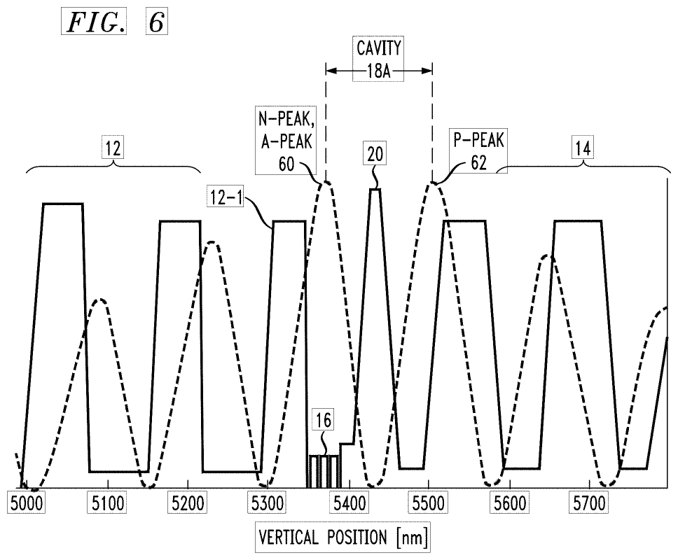

In another embodiment of the present invention, the length of cavity 18 may be decreased to the value of λ/2 by placing the closest mirror pair of first DBR 12 (denoted as 12-1) immediately adjacent to active region 16. FIG. 6 illustrates this embodiment, showing DBR pair 12-1 as located adjacent to active region 16. The field intensity plot associated with this configuration is also plotted in FIG. 6 and shows that the intensity peak associated with active region 16 (denoted as A-peak 60) exhibits an even stronger intensity than the embodiment discussed above in association with FIGS. 3 and 4. The additional increase in intensity functions to further lower the threshold current, increasing the slope efficiency of the device. Here, laser cavity 18A is defined as the region extending between A-peak 60 and P-peak 64, which encompasses only one-half of the complete wavelength cycle. It follows that the reduction in the physical size of laser cavity 18A reduces the overall size of the VCSEL as well, reducing the internal loss in the device which again allows for the threshold current to be reduced and provide a higher slope efficiency.

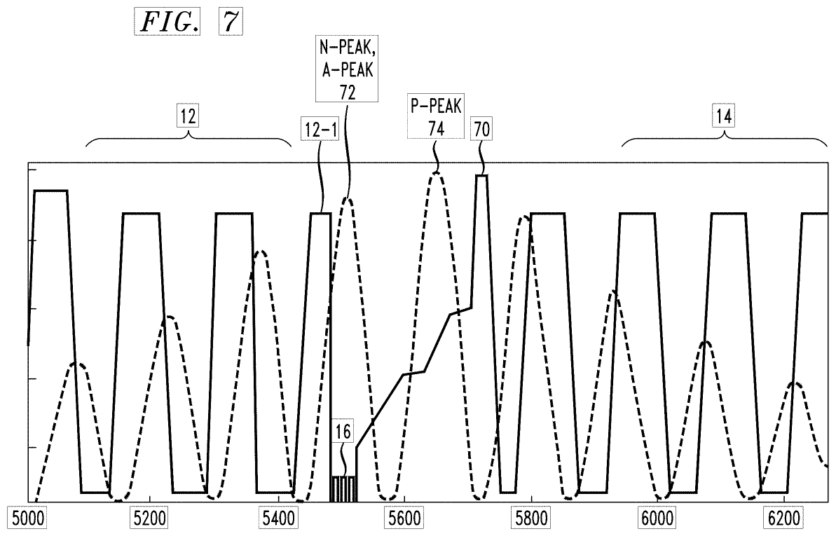

A modified version of the VCSEL associated with FIG. 6 is defined by the plots shown in FIG. 7. As with the structure described above in association with FIG. 6, the cavity length is shortened to the value of λ/2 by placing the closest mirror pair of first DBR 12 (defined as 12-1) immediately adjacent to active region 16. In this case, however, the oxide aperture layer (defined by shaded layer 70 in FIG. 7) is located outside the defined cavity of the structure (as defined by A-peak 72 and P-peak 74). While outside of the actual laser cavity, the increase in intensity of the field at active region 16 over conventional prior art structures (compare A-peak 60 to the drawing of FIG. 2) still allows for the threshold current to be reduced.

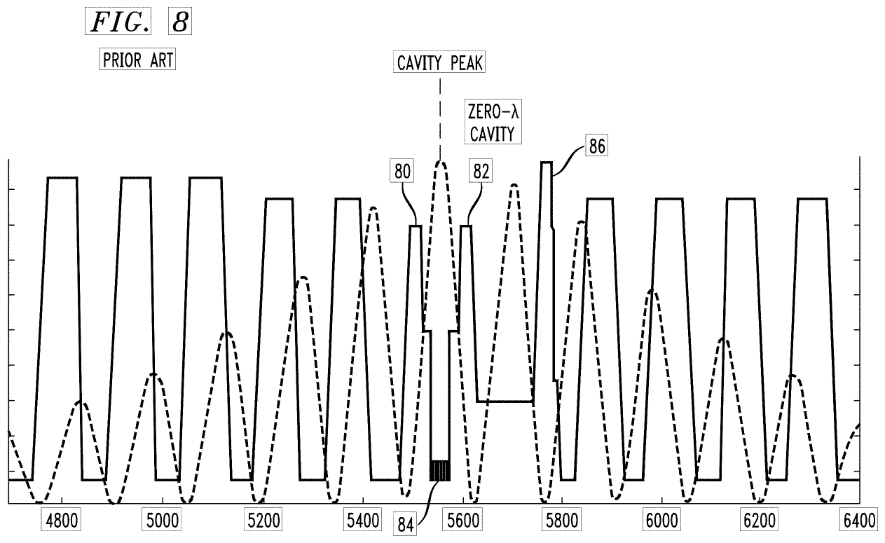

While typically the aluminum content within the laser cavity of a conventional VCSEL is monotonically decreasing as approaching the active region (as shown by the arrows in prior art FIG. 2), there are other prior art arrangements where after a period of decrease there is a spike in aluminum content in proximity to the active region (within both DBR structures). Referred to as an “inverted cavity” design, FIG. 8 illustrates the plots associated with this prior art form, specifically illustrating higher Al content layers 80 and 82 on either side of active region 84. This structure may also be described as a “zero-λ, cavity”, since the N-, A-, and P-peak intensities in the standing wave all coincide. While exhibiting some benefits over the conventional prior art configuration depicted in FIG. 2 (particularly in terms of increasing the intensity of the peak associated with the active region), its included oxide aperture layer 86 remains well separated from active region 84, as typically found in the prior art. As such, this prior art arrangement retains problems associated with current spread, optical beam confinement, numerical aperture, and the like, as discussed above.

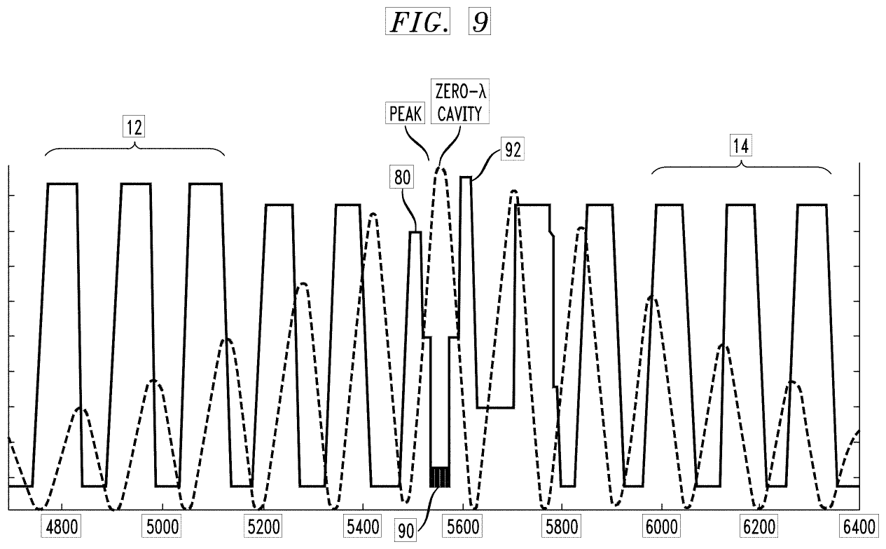

Yet another embodiment of the present invention may be contemplated by taking into consideration the prior inverse cavity structure of FIG. 8. In particular, FIG. 9 illustrates a “zero-λ, cavity” embodiment of the present invention, utilizing the inverted cavity VCSEL structure for the portion associated with the bottom DBR (i.e., include a high aluminum content layer 80 adjacent to active region 90), while replacing high aluminum content layer 82 of the prior art configuration with an oxide aperture layer 92.

While the foregoing is directed to embodiments of the present invention, other and further embodiments of the invention may be devised without departing from the basic scope thereof, which is determined by the claims that follow.

What is claimed is:

1. A vertical cavity surface emitting laser (VCSEL) comprising:
a first distributed Bragg reflector (DBR) formed on a substrate;
a second DBR positioned over the first DBR, where each DBR comprising a stack of layers of alternating refractive index value, the combination of the first DBR and second DBR forming a resonant structure supporting a standing wave of lasing field intensity;
an active region comprising an MQW structure formed between the first DBR and the second DBR, with a laser cavity defined as spanning between a first standing wave intensity peak and a second standing wave intensity peak closest to either side of the active region; and
an oxide aperture layer located within the laser cavity between the active region and the second DBR.

2. A VCSEL as defined in claim 1 wherein the oxide aperture layer is located at a null in the standing wave within the laser cavity.

3. A VCSEL as defined in claim 1 wherein the first DBR is positioned spaced apart from the active region, with the laser cavity supporting a full period of the standing wave (λ).

4. A VCSEL as defined in claim 1 wherein the first DBR is positioned adjacent to the active region, with the laser cavity supporting a half period of the standing wave (λ/2).

5. A VCSEL as defined in claim 1 wherein the laser cavity exhibits an inverted structure.

6. A vertical cavity surface emitting laser (VCSEL) comprising:
a first distributed Bragg reflector (DBR) formed on a substrate;
a second DBR positioned over the first DBR, where each DBR comprising a stack of layers of alternating refractive index value, the combination of the first DBR and second DBR forming a resonant structure supporting a standing wave of lasing field intensity;
an active region comprising an MQW structure formed immediately adjacent to the first DBR, with a laser cavity defined as spanning between a first standing wave intensity peak and a second standing wave intensity peak closest to or coincident with the active region, the first standing wave intensity peak coincident with the active region; and
an oxide aperture layer located beyond the second standing wave intensity peak.
